(19) United States
(12) Patent Application Publication
(10) Pub. No.: US 2012/0126241 A1
(43) Pub. Date: May 24, 2012

(54) GROUP III NITRIDE SEMICONDUCTOR LIGHT-EMITTING DEVICE AND PRODUCTION METHOD THEREFOR

(75) Inventors: Koji OKUNO, Kiyosu-shi (JP); Atsushi MIYAZAKI, Kiyosu-shi (JP)

(73) Assignee: Toyoda Gosei Co., Ltd., Aichi-ken (JP)

(21) Appl. No.: 13/302,983

(22) Filed: Nov. 22, 2011

(30) Foreign Application Priority Data
Nov. 24, 2010 (JP) 2010-261166

(51) Int. Cl. H01L 33/32

(52) U.S. Cl. 257/76; 257/E33.025

(57) ABSTRACT

A Group III nitride semiconductor light-emitting device includes a sapphire substrate having an embossment on a surface thereof; and an n-type layer, a light-emitting layer, and a p-type layer, which are sequentially stacked on the embossed surface of the sapphire substrate via a buffer layer, and each of which is formed of a Group HI nitride semiconductor. The embossment has a structure including a first stripe-pattern embossment which is formed on a surface of the sapphire substrate, and whose stripe direction corresponds to the x-axis direction; and a second stripe-pattern embossment which is formed atop the first stripe-pattern embossment, and whose stripe direction corresponds to the y-axis direction, the y-axis direction being orthogonal to the x-axis direction.

### BACKGROUND OF THE INVENTION

1. Field of the Invention

The present invention relates to a Group III nitride semiconductor light-emitting device whose light extraction performance is improved by forming an embossment on a sapphire substrate included in the device.

2. Background Art

In recent years, Group III nitride semiconductor light-emitting devices have begun to be used in general illumination applications, and have been strongly required to exhibit improved light extraction performance. Patent Document 1 discloses a method for improving the light extraction performance of a semiconductor light-emitting device, in which an embossment is formed on a sapphire substrate. In the case of a semiconductor light-emitting device including a flat sapphire substrate having no embossment, light propagated in the device in a direction horizontal to the substrate is confined in semiconductor layers and is attenuated through, for example, repeated multiple reflection. In contrast, in the case of a semiconductor light-emitting device including a sapphire substrate having an embossment, light propagated in the device in a direction horizontal to the substrate can be reflected or scattered in a direction perpendicular to the substrate and can be extracted to the outside, whereby light extraction performance can be improved. Such an embossment may have, for example, a stripe pattern or a dot pattern as viewed from above.

Patent Document 1: Japanese Patent Application Laid-Open (kokai) No. 2003-318441

However, when a stripe-pattern embossment is formed on a sapphire substrate, since no difference in level is provided in the direction of the stripe, light propagated along the stripe may fail to be reflected or scattered upward, resulting in insufficient improvement of light extraction performance.

Meanwhile, even when dents or mesas are periodically arranged on a sapphire substrate in a dot pattern as viewed from above, an appropriate space must be provided between dents (or mesas) for filling the embossment with GaN and forming a flat GaN layer on the substrate. Therefore, in some regions of the substrate, no difference in level is provided in a specific direction, resulting in insufficient improvement of light extraction performance.

### SUMMARY OF THE INVENTION

In view of the foregoing, an object of the present invention is to realize a Group III nitride semiconductor light-emitting device exhibiting further improved light extraction performance.

In a first aspect of the present invention, there is provided a Group III nitride semiconductor light-emitting device comprising a sapphire substrate, and a layered structure provided on the sapphire substrate and formed of a Group III nitride semiconductor, wherein the sapphire substrate has an embossment on the surface on the layered structure side; and the embossment has a structure in which one or more differences in level are provided in any cross section perpendicular to the main surface of the sapphire substrate, and two or more differences in level are provided in a specific cross section perpendicular to the main surface of the sapphire substrate.

As used herein, “Group III nitride semiconductor” encompasses a semiconductor represented by the formula AlₓGa_{y}In_{z}N (x+y+z=1, 0≦x, y, z≦1); such a semiconductor in which a portion of Al, Ga, or In is substituted by another Group 13 element (i.e., B or Tl), or a portion of N is substituted by another Group 15 element (i.e., P, As, Sb, or Bi). Specific examples of the Group III nitride semiconductor include those containing at least Ga, such as GaN, InGaN, AlGaN, and AlGaInN. Generally, Si is used as an n-type impurity, and Mg is used as a p-type impurity.

No particular limitation is imposed on the structure of the embossment provided on the sapphire substrate, so long as, as described above, one or more differences in level are provided in any cross section perpendicular to the main surface of the sapphire substrate, and two or more differences in level are provided in a specific cross section perpendicular to the main surface of the sapphire substrate. For example, the embossment of the substrate may have a structure including a first stripe-pattern embossment, and a second stripe-pattern embossment provided atop the first stripe-pattern embossment, wherein the stripe direction of the first stripe-pattern embossment (first direction) is different from the stripe direction of the second stripe-pattern embossment (second direction). The first stripe-pattern embossment and the second stripe-pattern embossment may differ from each other in, for example, the intervals of dents (or mesas), the depth of dents, the angle between side surfaces of dents (or mesas) and the main surface of the sapphire substrate, or the shape of dents (or mesas) as viewed in a cross section perpendicular to the stripe direction.

From the viewpoint of improvement of light extraction performance, the angle between the first direction and the second direction is preferably 30° to 150°, more preferably 90°. Also, from the viewpoint of improvement of light extraction performance, preferably, side surfaces of dents (or mesas) of the stripe-pattern embossment are inclined by 40° to 80° with respect to the sapphire substrate.

Other examples of the structure of the embossment of the substrate are as follows. For example, the embossment of the substrate may have a structure including a stripe-pattern embossment, and a dot-pattern embossment provided atop the stripe-pattern embossment, wherein the dot-pattern embossment includes a plurality of dents or mesas which are arranged in a grid pattern. Dents or mesas of the dot-pattern embossment may have, for example, a truncated pyramidal, truncated conical, prismatic, cylindrical, pyramidal, conical, or hemispherical shape. Dents or mesas of the dot-pattern embossment may be arranged in a grid pattern (e.g., quadrangular or triangular grid pattern). Alternatively, the embossment of the substrate may have a structure including a dot-pattern embossment and a stripe-pattern embossment provided atop the dot-pattern embossment, wherein the dot-pattern embossment includes a plurality of dents or mesas which are arranged in a grid pattern. Side surfaces of dents (or mesas) of the dot-pattern embossment are preferably inclined by 40° to 80° with respect to the main surface of the sapphire substrate. When the angle falls within the above range, light extraction performance can be further improved.

A second aspect of the present invention is drawn to a specific embodiment of the Group III nitride semiconductor light-emitting device according to the first aspect of the invention, wherein the embossment has a structure including a first stripe-pattern embossment formed on the surface of the sapphire substrate on the layered structure side, the first stripe-pattern embossment including a plurality of first grooves which are arranged in a stripe pattern as viewed from above and are aligned parallel to a first direction; and a second stripe-pattern embossment formed atop the first stripe-pattern embossment, the second stripe-pattern embossment including a plurality of second grooves which are arranged in a stripe pattern as viewed from above and are aligned parallel to a second direction, the second direction differing from the first direction.

A third aspect of the present invention is drawn to a specific embodiment of the Group III nitride semiconductor light-emitting device according to the second aspect of the invention, wherein the first direction is orthogonal to the second direction.

A fourth aspect of the present invention is drawn to a specific embodiment of the Group III nitride semiconductor light-emitting device according to the first aspect of the invention, wherein the embossment has a structure including a stripe-pattern embossment formed on the surface of the sapphire substrate on the layered structure side, the stripe-pattern embossment including a plurality of grooves which are arranged in a stripe pattern as viewed from above and are aligned parallel to a specific direction; and a dot-pattern embossment formed atop the stripe-pattern embossment, the dot-pattern embossment including mesas or dents which are arranged in a grid pattern as viewed from above.

A fifth aspect of the present invention is drawn to a specific embodiment of the Group III nitride semiconductor light-emitting device according to the first aspect of the invention, wherein the embossment has a structure including a dot-pattern embossment formed on the surface of the sapphire substrate on the layered structure side, the dot-pattern embossment including mesas or dents which are arranged in a grid pattern as viewed from above; and a stripe-pattern embossment formed atop the dot-pattern embossment, the stripe-pattern embossment including a plurality of grooves which are arranged in a stripe pattern as viewed from above and are aligned parallel to a specific direction.

According to the present invention, since the embossment of the sapphire substrate exhibits the effect of reflecting light propagated in any direction in the device, light extraction performance can be further improved.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 shows the configuration of a Group III nitride semiconductor light-emitting device according to Embodiment 1;

FIGS. 2A and 2B show embossments formed on the top surface of a sapphire substrate 10;

FIGS. 3A and 3B are sketches showing processes for forming embossments on the top surface of the sapphire substrate 10;

FIGS. 4A and 4B are sketches showing processes for producing the Group III nitride semiconductor light-emitting device according to Embodiment 1; and

FIG. 5 is a top view of another embossment.

### DETAILED DESCRIPTION OF PREFERRED EMBODIMENTS

A specific embodiment of the present invention will next be described with reference to the drawings. However, the present invention is not limited to the embodiment.

### Embodiment 1

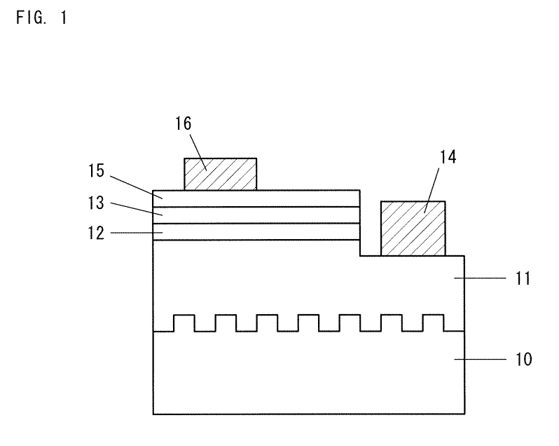

FIG. 1 shows the configuration of a Group III nitride semiconductor light-emitting device according to Embodiment 1. The Group III nitride semiconductor light-emitting device according to Embodiment 1 includes a sapphire substrate 10 having an embossment on a surface thereof; and an n-type layer 11, a light-emitting layer 12, and a p-type layer 13, which are sequentially deposited on the embossed surface of the sapphire substrate 10 via a buffer layer (not illustrated), and each of which is formed of a Group III nitride semiconductor. The layered structure of the present invention corresponds to a structure including the n-type layer 11, the light-emitting layer 12, and the p-type layer 13. A portion of the light-emitting layer 12 and a portion of the p-type layer 13 are removed, and the corresponding portion of the surface of the n-type layer 11 is exposed. An n-electrode 14 is formed on the exposed portion of the surface of the n-type layer 11. An ITO transparent electrode 15 is formed on almost the entire top surface of the p-type layer 13, and a p-electrode 16 is formed on the transparent electrode 15. The Group III nitride semiconductor light-emitting device according to Embodiment 1 is of a face-up type.

Each of the n-type layer 11, the light-emitting layer 12, and the p-type layer 13 may have any of conventionally known structures. For example, the n-type layer 11 has a structure in which a GaN n-type contact layer doped with Si at high concentration and a GaN n-cladding layer are sequentially deposited on the sapphire substrate 10. For example, the light-emitting layer 12 has an MQW structure in which GaN barrier layers and InGaN well layers are alternately deposited. For example, the p-type layer 13 has a structure in which an AlGaN p-cladding layer doped with Mg and a GaN p-contact layer doped with Mg are sequentially deposited on the light-emitting layer 12.

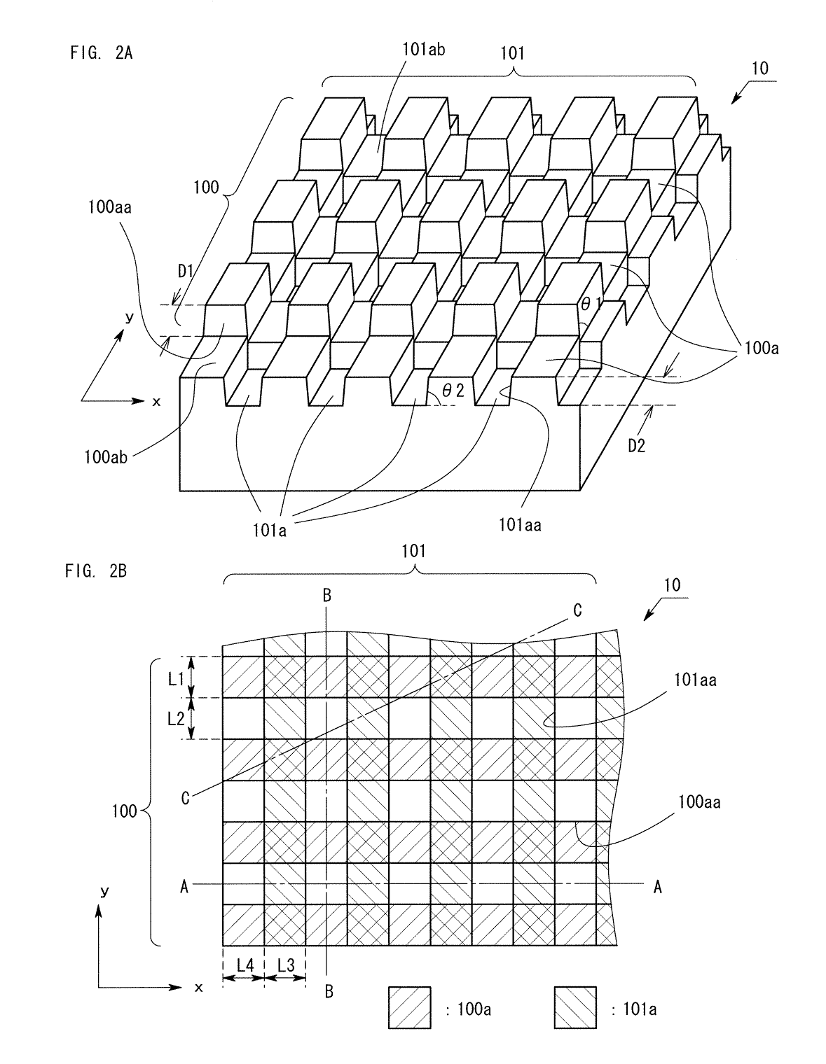

FIG. 2A is a perspective view of an embossment formed on the top surface of the sapphire substrate 10, and FIG. 2B is a top view of the sapphire substrate 10. As shown in FIGS. 2A and 2B, a first stripe-pattern embossment 100 is formed on the top surface of the sapphire substrate 10, and a second stripe-pattern embossment 101 is formed atop the first stripe-pattern embossment 100.

The first stripe-pattern embossment 100 includes a plurality of first grooves 100a which are arranged at regular intervals and parallel to a specific direction (i.e., the x-axis direction in FIG. 2, corresponding to the first direction of the present invention). Preferably, the width L1 of each first groove 100a is 0.1 μm to 20 μm, and the distance L2 between adjacent first grooves 100a is 0.1 μm to 20 μm. This is because, when the width L1 and the distance L2 fall within the above ranges, light extraction performance can be further improved. More preferably, the width L1 is 0.1 μm to 5 μm, and the distance L2 is 0.1 μm to 5 μm. Preferably, the angle θ1 between each of side surfaces 100aa of the first grooves 100a and the main surface of the sapphire substrate 10 is 40° to 80°. This is because, when the angle θ1 falls within the above range, light extraction performance can be further improved. More preferably, the angle θ1 is 50° to 70°. Preferably, the depth D1 of each first groove 100a is 0.1 μm to 3 μm. This is because, when the depth D1 falls within the above range, light extraction performance can be further improved. More preferably, the depth D1 is 0.5 μm to 2 μm.

The second stripe-pattern embossment 101 includes a plurality of second grooves 101a which are arranged at regular intervals and parallel to a direction orthogonal to the x-axis direction (i.e., the y-axis direction in FIG. 2, corresponding to the second direction of the present invention). On bottom surfaces of the second grooves 101a, dents or mesas are provided along the first stripe-pattern embossment 100. Preferably, the width L3 of each second groove 101a is 0.1 μm to 20 μm, and the distance L4 between adjacent second grooves 101a is 0.1 μm to 20 μm. This is because, when the width L3 and the distance L4 fall within the above ranges, light extraction performance can be further improved. More preferably, the width L3 is 0.1 μm to 5 μm, and the distance L4 is 0.1 μm to 5 μm. Preferably, the angle θ2 between each of side surfaces 101aa of the second grooves 101a and the main surface of the sapphire substrate 10° is 40° to 80°. This is because, when the angle θ2 falls within the above range, light extraction performance can be further improved. More preferably, the angle θ2 is 50° to 70°. Preferably, the depth D2 of each second groove 101a is 0.1 μm to 3 μm. This is because, when the depth D2 falls within the above range, light extraction performance can be further improved. More preferably, the depth D2 is 0.5 μm to 2 μm. The depth D1 of each first groove 100a may be equal to or different from the depth D2 of each second groove 101a. Also, the width L1 of each first groove 100a may be equal to or different from the width L3 of each second groove 101a, and the distance L2 between adjacent first grooves 100a may be equal to or different from the distance L4 between adjacent second grooves 101a. Also, the angle θ1 may be equal to or different from the angle θ2.

The stripe direction of the first stripe-pattern embossment 100 (i.e., the x-axis direction) is orthogonal to the stripe direction of the second stripe-pattern embossment 101 (i.e., the y-axis direction), but these stripe directions are not necessarily orthogonal to each other. When the stripe direction of the first stripe-pattern embossment 100 is inclined by 30° to 150° with respect to the stripe direction of the second stripe-pattern embossment 101, light extraction performance can be improved. However, most preferably, these stripe directions are orthogonal to each other as described in this embodiment.

In the embossment provided on the sapphire substrate 10, one or more differences in level are provided in any cross section perpendicular to the main surface of the substrate, and two or more differences in level are provided in a specific cross section perpendicular to the main surface of the substrate. For example, in a cross section as taken along line A-A parallel to the x-axis direction, no difference in level is provided by the first stripe-pattern embossment 100, but one difference in level is provided by the second stripe-pattern embossment 101. In a cross section as taken along line B-B parallel to the y-axis direction, no difference in level is provided by the second stripe-pattern embossment 101, but one difference in level is provided by the first stripe-pattern embossment 100. Meanwhile, in a cross section as taken along line C-C shown in FIG. 2, three differences in level are provided by the first stripe-pattern embossment 100 and the second stripe-pattern embossment 101.

When the embossment is formed as described above, light propagated in the device in a direction parallel to the main surface of the sapphire substrate 10 can be irregularly reflected in any direction by means of a difference in level provided by the first stripe-pattern embossment 100 or the second stripe-pattern embossment 101, and the thus-reflected light can be extracted on the light extraction side (i.e., on the n-electrode 14 side or the p-electrode 16 side). Therefore, the Group III nitride semiconductor light-emitting device according to Embodiment 1 exhibits improved light extraction performance, as compared with a conventional Group III nitride semiconductor light-emitting device.

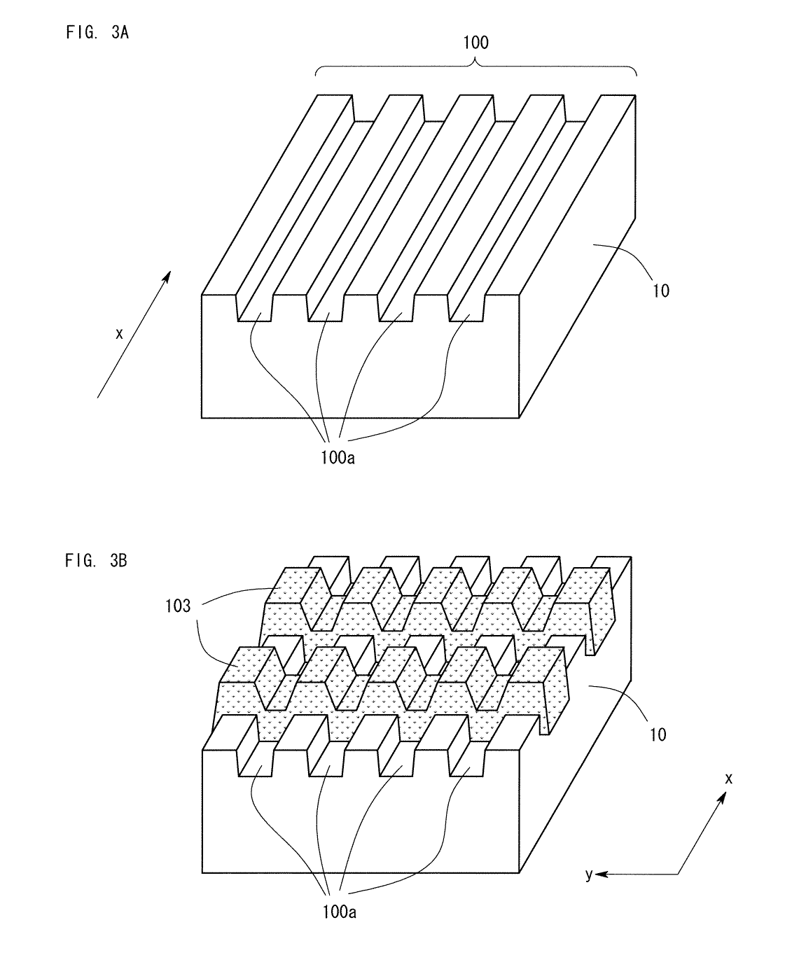

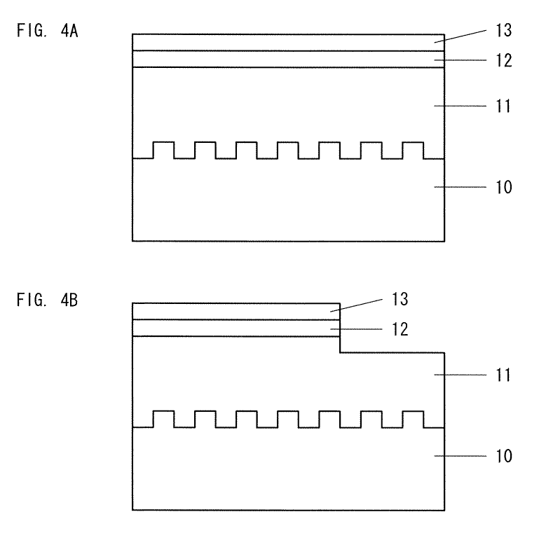

Next will be described processes for producing the Group III nitride semiconductor light-emitting device according to Embodiment 1 with reference to FIGS. 3 and 4.

Now will be described formation of an embossment on a sapphire substrate 10. Firstly, as shown in FIG. 3A, a first stripe-pattern embossment 100 is formed on the top surface of the sapphire substrate 10 through photolithography and dry etching, so that first grooves 100a parallel to the x-axis direction are periodically arranged at specific intervals.

Subsequently, as shown in FIG. 3B, a stripe-pattern photomask 103 is formed through photolithography on the first stripe-pattern embossment 100 provided on the top surface of the sapphire substrate 10, so that openings of the photomask are periodically arranged at specific intervals (in the x-axis direction) and parallel to the y-axis direction, which is orthogonal to the x-axis direction. Thereafter, a portion of the top surface of the sapphire substrate 10 which is not covered with the photomask 103 is subjected to dry etching, and then the photomask 103 is removed, to thereby form an embossment shown in FIG. 2 on the top surface of the sapphire substrate 10.

When the top surface of the sapphire substrate 10 is subjected to dry etching through different two processes as described above, edges of the thus-formed mesas can be prevented from becoming round, and the embossment can be formed with high precision.

Subsequently, thermal cleaning is carried out for recovery from damage to the sapphire substrate 10 due to formation of the aforementioned embossment, or removing impurities from the surface of the sapphire substrate 10. Thermal cleaning corresponds to, for example, thermal treatment in a hydrogen atmosphere at 1,000° C. to 1,200° C.

Next, on the sapphire substrate 10 on which the embossment has been formed as described above, an n-type layer 11, a light-emitting layer 12, and a p-type layer 13 are sequentially formed by MOCVD via an AlN buffer layer (not illustrated) (FIG. 4A). The raw material gases, etc. employed for MOCVD are as follows: ammonia (NH₃) as a nitrogen source, trimethylgallium (Ga(CH₃)₃) as a Ga source, trimethylindium (In(CH₃)₃) as an In source, trimethylaluminum (Al(CH₃)₃) as an Al source, silane (SiH₄) as an n-type doping gas, cyclopentadienylmagnesium (Mg(C₅H₅)₂) as a p-type doping gas, and H₂ or N₂ as a carrier gas.

Thereafter, a portion of the p-type layer 13 and a portion of the light-emitting layer 12 are removed through dry etching, to thereby expose the corresponding portion of the surface of the n-type layer 11 (FIG. 4B). Then, a transparent electrode 15 is formed on almost the entire top surface of the p-type layer 13; an n-electrode 14 is formed on the thus-exposed portion of the surface of the n-type layer 11; and a p-electrode 16 is formed on the transparent electrode 15. Thus, the Group III nitride semiconductor light-emitting device according to Embodiment 1 is produced.

In Examples 1-1 to 1-6, devices corresponding to the Group III nitride semiconductor light-emitting device of Embodiment 1 were produced by varying the width L1, distance L2, and depth D1 of each first groove 100a forming the first stripe-pattern embossment 100, the angle θ1 of each side surface 100aa, the width L3, distance L4, and depth D2 of each second groove 101a forming the second stripe-pattern embossment 101, and the angle θ2 of each side surface 101aa. L1, L2, L3 and L4 are the value on the contact surface to the sapphire substrate 10. The thus-produced devices were compared with devices of Comparative Examples 1 and 2 in terms of light output in a direction perpendicular to the main surface of the device (axial light output). Comparative Example 1 or 2 corresponds to the case where an embossment is formed on the top surface of a sapphire substrate so that a plurality of truncated conical mesas are arranged in a triangular grid pattern (diameter of each mesa: 3 μm, distance between adjacent mesas: 2 μm). Comparative Example 1 corresponds to the case where the side surface of each mesa is inclined by 80° with respect to the main surface of the sapphire substrate, and the height of each mesa is 0.7 μm. Comparative Example 2 corresponds to the case where the side surface of each mesa is inclined by 60° with respect to the main surface of the sapphire substrate, and the height of each mesa is 1.4 μm. The diameter of mesa and the distance between adjacent mesas are the value on the contact surface to the sapphire substrate. The axial light output of the device of Comparative Example 2 was found to be 1.11 times that of the device of Comparative Example 1.

### EXAMPLE 1-1

The width L1, distance L2, and depth D1 of each first groove 100a were adjusted to 2 μm, 2 μm, and 0.7 μm, respectively; the angle θ1 of each side surface 100aa was adjusted to 80°; the width L3, distance L4, and depth D2 of each second groove 101a were adjusted to 1.5 μm, 1.5 μm, and 0.7 μm, respectively; and the angle θ2 of each side surface 101aa was adjusted to 80°. The axial light output of the thus-produced device was measured and found to be 1.19 times that of the device of Comparative Example 1.

### EXAMPLE 1-2

The width L1, distance L2, and depth Dl of each first groove 100a were adjusted to 1.5 μm, 1.5 μm, and 0.7 μm, respectively; the angle θ1 of each side surface 100aa was adjusted to 80°; the width L3, distance L4, and depth D2 of each second groove 101a were adjusted to 1.5 μm, 1.5 μm, and 0.7 μm, respectively; and the angle θ2 of each side surface 101aa was adjusted to 80°. The axial light output of the thus-produced device was measured and found to be 1.17 times that of the device of Comparative Example 1.

### EXAMPLE 1-3

The width L1, distance L2, and depth Dl of each first groove 100a were adjusted to 2 μm, 2 μm, and 1.4 μm, respectively; the angle θ1 of each side surface 100aa was adjusted to 60°; the width L3, distance L4, and depth D2 of each second groove 101a were adjusted to 1.5 μm, 1.5 μm, and 0.7 μm, respectively; and the angle θ2 of each side surface 101aa was adjusted to 80°. The axial light output of the thus-produced device was measured and found to be 1.29 times that of the device of Comparative Example 1.

### EXAMPLE 1-4

The width L1, distance L2, and depth D1 of each first groove 100a were adjusted to 1.5 μm, 1.5 μm, and 1.4 μm, respectively; the angle θ1 of each side surface 100aa was adjusted to 60°; the width L3, distance L4, and depth θ2 of each second groove 101a were adjusted to 1.5 μm, 1.5 μm, and 0.7 μm, respectively; and the angle θ2 of each side surface 101aa was adjusted to 80°. The axial light output of the thus-produced device was measured and found to be 1.29 times that of the device of Comparative Example 1.

### EXAMPLE 1-5

The width L1, distance L2, and depth D1 of each first groove 100a were adjusted to 2 μm, 2 μm, and 0.7 μm, respectively; the angle θ1 of each side surface 100aa was adjusted to 80°; the width L3, distance L4, and depth D2 of each second groove 101a were adjusted to 1.5 μm, 1.5 μm, and 1.4 μm, respectively; and the angle θ2 of each side surface 101aa was adjusted to 60°. The axial light output of the thus-produced device was measured and found to be 1.34 times that of the device of Comparative Example 1.

### EXAMPLE 1-6

The width L1, distance L2, and depth D1 of each first groove 100a were adjusted to 1.5 μm, 1.5 μm, and 0.7 μm, respectively; the angle θ1 of each side surface 100aa was adjusted to 80°; the width L3, distance L4, and depth D2 of each second groove 101a were adjusted to 1.5 μm, 1.5 μm, and 1.4 μm, respectively; and the angle θ2 of each side surface 101aa was adjusted to 60°. The axial light output of the thus-produced device was measured and found to be 1.28 times that of the device of Comparative Example 1.

Thus, each of the devices of Examples 1-1 to 1-6 exhibited axial light output higher than that of the device of Comparative Example 1 or 2.

In the embodiment as described above the depth of the first grooves of the first stripe-pattern may be different from the depth of the second grooves of the second stripe-pattern embossment. Also the depth of the first grooves of the first stripe-pattern may be equal to the depth of the second grooves of the second stripe-pattern embossment.

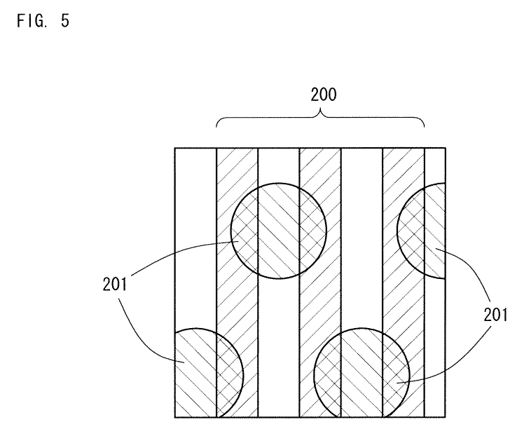

The embossment provided on the sapphire substrate 10 is not limited to that described in Embodiment 1. The embossment may have any structure, so long as one or more differences in level are provided in any cross section perpendicular to the main surface of the sapphire substrate 10, and two or more differences in level are provided in a specific cross section perpendicular to the main surface of the sapphire substrate 10. For example, the embossment may have a pattern as shown in the plan view of FIG. 5. The embossment shown in FIG. 5 has a structure including a stripe-pattern embossment 200, and a dot-pattern embossment 201 formed atop the stripe-pattern embossment 200, wherein the dot-pattern embossment 201 includes mesas or dents which are arranged in a triangular grid pattern; or a structure including the dot-pattern embossment 201 and the stripe-pattern embossment 200 formed atop the dot-pattern embossment 201. Similar to the case of Embodiment 1, a Group III nitride semiconductor light-emitting device including a sapphire substrate 10 having such an embodiment on a surface thereof exhibits improved light extraction performance.

The Group III nitride semiconductor light-emitting device according to Embodiment 1 is of a face-up type. However, the present invention can also be applied to a flip-chip device.

The Group III nitride semiconductor light-emitting device of the present invention can be employed in, for example, a display apparatus or an illumination apparatus.

What is claimed is:

1. A Group III nitride semiconductor light-emitting device comprising a sapphire substrate, and a layered structure provided on the sapphire substrate and formed of a Group III nitride semiconductor, wherein the sapphire substrate has an embossment on the surface on the layered structure side; and the embossment has a structure in which one or more differences in level are provided in any cross section perpendicular to the main surface of the sapphire substrate, and two or more differences in level are provided in a specific cross section perpendicular to the main surface of the sapphire substrate.

2. A Group III nitride semiconductor light-emitting device according to claim 1, wherein the embossment has a structure including a first stripe-pattern embossment formed on the surface of the sapphire substrate on the layered structure side, the first stripe-pattern embossment including a plurality of first grooves which are arranged in a stripe pattern as viewed from above and are aligned parallel to a first direction; and a second stripe-pattern embossment formed atop the first stripe-pattern embossment, the second stripe-pattern embossment including a plurality of second grooves which are arranged in a stripe pattern as viewed from above and are aligned parallel to a second direction, the second direction differing from the first direction.

3. A Group III nitride semiconductor light-emitting device according to claim 2, wherein the first direction is orthogonal to the second direction.

4. A Group III nitride semiconductor light-emitting device according to claim 1, wherein the embossment has a structure including a stripe-pattern embossment formed on the surface of the sapphire substrate on the layered structure side, the stripe-pattern embossment including a plurality of grooves which are arranged in a stripe pattern as viewed from above and are aligned parallel to a specific direction; and a dot-pattern embossment formed atop the stripe-pattern embossment, the dot-pattern embossment including mesas or dents which are arranged in a grid pattern as viewed from above.

5. A Group III nitride semiconductor light-emitting device according to claim 1, wherein the embossment has a structure including a dot-pattern embossment formed on the surface of the sapphire substrate on the layered structure side, the dot-pattern embossment including mesas or dents which are arranged in a grid pattern as viewed from above; and a stripe-pattern embossment formed atop the dot-pattern embossment, the stripe-pattern embossment including a plurality of grooves which are arranged in a stripe pattern as viewed from above and are aligned parallel to a specific direction.

6. A Group III nitride semiconductor light-emitting device according to claim 2, wherein depths of the first grooves of the first stripe-pattern embossment are different from depths of the second grooves of the second stripe-pattern embossment.

7. A Group III nitride semiconductor light-emitting device according to claim 3, wherein depths of the first grooves of the first stripe-pattern embossment are different from depths of the second grooves of the second stripe-pattern embossment.

8. A Group III nitride semiconductor light-emitting device according to claim 2, wherein depths of the first grooves of the first stripe-pattern embossment are equal to depths of the second grooves of the second stripe-pattern embossment.

9. A Group III nitride semiconductor light-emitting device according to claim 3, wherein depths of the first grooves of the first stripe-pattern embossment are equal to depths of the second grooves of the second stripe-pattern embossment.

10. A Group III nitride semiconductor light-emitting device according to claim 4, wherein depths of the grooves of the stripe-pattern embossment are different from height of mesas or depths of the dents of the dot-pattern embossment.

11. A Group III nitride semiconductor light-emitting device according to claim 5, wherein depths of the grooves of the stripe-pattern embossment are different from height of mesas or depths of the dents of the dot-pattern embossment.

12. A Group III nitride semiconductor light-emitting device according to claim 4, wherein depths of the grooves of the stripe-pattern embossment are equal to height of mesas or depths of the dents of the dot-pattern embossment.

13. A Group III nitride semiconductor light-emitting device according to claim 5, wherein depths of the grooves of the stripe-pattern embossment are equal to height of mesas
or depths of the dents of the dot-pattern embossment.
